(19) United States
(12) Patent Application Publication
(10) Pub. No.: US 2024/0134291 A1
(43) Pub. Date: Apr. 25, 2024

(54) SEMICONDUCTOR WAFER, PROCESSING APPARATUS FOR OVERLAY SHIFT AND PROCESSING METHOD THEREOF

(71) Applicant: Winbond Electronics Corp., Taichung City (TW)

(72) Inventors: Meng-Hsien TSAI, Taichung City (TW); Cheng-Shuai LI, Taichung City (TW); Yueh-Feng LU, Taichung City (TW); Kao-Tsair TSAI, Taichung City (TW)

(21) Appl. No.: 18/486,395

(22) Filed: Oct. 12, 2023

(30) Foreign Application Priority Data
Oct. 23, 2022 (TW) 111140233

(51) Int. Cl. G03F 7/00; H01L 21/66; H01L 23/544

(52) U.S. Cl. CPC G03F 7/70633; G03F 7/70683; H01L 22/12; H01L 23/544; H01L 2223/54426

(57) ABSTRACT

A processing apparatus for overlay shift includes a storage unit and a control unit, and is applicable to a semiconductor wafer with several inspection regions. Each of the inspection regions has several sets of overlay marks for inspection. One set of overlay marks includes an original alignment mark without any overlay shift, and several split alignment marks with predetermined overlay shifts arranged near the original alignment mark. The original after-etch inspection (AEI) overlay data of the inspection regions is stored in the storage unit. The after-develop inspection (ADI) overlay data of the original alignment mark and the split alignment marks are compared with the original AEI overlay data by the control unit, thereby acquiring ADI pre-bias data of the original alignment mark and the split alignment marks. The control unit determines whether an overlay shift compensation is performed according to the acquired ADI pre-bias data.

### CROSS REFERENCE TO RELATED APPLICATIONS

This Application is based on, and claims priority of TW Application No. 111140233 filed on Oct. 24, 2022, the entirety of which is incorporated by reference herein.

### BACKGROUND

### Background of the Invention

### Technical Field

The disclosure relates to a data processing apparatus and method, and in particular it relates to a processing apparatus, a processing method and a semiconductor wafer applied in the same, thereby predicting the degree of overlay shift in advance and performing compensation instantly.

### Description of the Related Art

In the semiconductor manufacturing process, the minimum line width is generally referred to as a critical dimension, which is used as one of the measurement indicators of process technology. In the manufacture of integrated circuits with ever smaller critical dimensions, the requirements for layer-to-layer overlay accuracy are getting higher and higher. Any process variation may cause an overlay shift between an upper layer and a lower layer. For example, the sputtering angle of the film material, the wafer warpage, the change of process equipment, or another factor may cause overlay shift in the layers.

In the semiconductor manufacturing process, the pattern of a target material layer is generally defined by a photolithography process. The defined pattern is then transferred to the target material layer through an etching process. In addition, several overlay marks are provided in the non-target region, and the shift of the overlay marks are correlated with the overlay shift of the actual target patterned layer in the target region (e.g., the chip region). An overlay measurement technology is applied to detect the overlay marks in the non-target region to adjust and control the alignment of the target patterned layer in the manufacturing process. The overlay measurement technology includes an after-develop inspection (ADI) performed on the target material layer before the etching process, and an after-etch inspection (AEI) performed on the target material layer after the etching process. Conventionally, the overlay accuracy between the layers are verified by the results of the AEI. However, overlay shift usually occurs in the deposition and lithography process stages of the target material layer, which leads to the overlay shift between the patterned target material layer after etching and a lower layer. In addition, manufacturing factors such as different deposition devices, different processing chambers, different products and different thicknesses of the film layers may cause a certain degree of overlay shift, which require that tests be run repeatedly for evaluations. In addition, it still requires inspecting the overlay shift of the patterned target material layer after etching to verify the overlay shift condition. Therefore, the conventional method for verifying the overlay shift of the patterned target material layer is time-consuming.

Thus, although existing overlay measurement technology and methods for improving overlay performance have been adequate for their intended purposes, they have not been entirely satisfactory in all respects.

### SUMMARY

The disclosure provides a semiconductor wafer, a processing apparatus and a processing method for overlay shift. The disclosure can improve the manufacturing process by solving the problem that the conventional processing method takes too much time and cannot monitor and predict the overlay shift in real time.

Some embodiments of the present disclosure provide a semiconductor wafer including several inspection regions. Each of the inspection regions includes several sets of overlay marks for inspection, and each of the sets of overlay marks includes an original alignment mark without any overlay shift and split alignment marks with predetermined overlay shifts, wherein the split alignment marks are arranged near the original alignment mark.

Some embodiments of the present disclosure provide a processing apparatus for overlay shift, which is applied to a semiconductor wafer with inspection regions. Each of the inspection regions includes several sets of overlay marks for inspection, and each of the sets of overlay marks includes an original alignment mark without any overlay shift and split alignment marks with predetermined overlay shifts. The split alignment marks are arranged near the original alignment mark. The processing apparatus for overlay shift includes a storage unit that stores the original after-etch inspection (AEI) overlay data of the inspection regions, and a control unit coupled to the storage unit. The control unit is configured to compare after-develop inspection (ADI) overlay data of the original alignment mark and the split alignment marks with the AEI overlay data, thereby acquiring ADI pre-bias data of the original alignment mark and the split alignment marks. Then, the control unit determines whether an overlay shift compensation is performed according to the acquired ADI pre-bias data.

Some embodiments of the present disclosure provide a processing method for overlay shift. The method includes receiving a wafer with several inspection regions, wherein each of the inspection regions includes sets of overlay marks for inspection. Each of the sets of overlay marks includes an original alignment mark without any overlay shift and split alignment marks with predetermined overlay shifts. The split alignment marks are arranged near the original alignment mark. The method further includes comparing ADI overlay data of the original alignment mark and the split alignment marks with the original AEI overlay data, thereby acquiring ADI pre-bias data of the original alignment mark and the split alignment marks. The method further includes determining whether an overlay shift compensation is performed according to the acquired ADI pre-bias data.

According to some embodiments, the provided processing method can be performed to predict overlay shift in advance by using a new design of overlay marks in the inspection regions of the wafer. According to the ADI pre-bias data, before an upper material layer is actually patterned, whether the patterned upper material layer is offset from a patterned lower material layer can be predicted in advance. Thus, the processing method of the embodiments improves the manufacturing process and enhances the accuracy of pattern formation in real time. Also, the prediction and early warning function of the processing method in accordance with some embodiments does shorten the time for testing and evaluating the overlay marks. The processing method of the embodiments can be applied in many aspects of related processes. For example, they can be applied to any stage of wafer manufacturing processes to predict whether the patterns of the upper and lower material layers (such as the wires and underlying conductive vias in a back-end-of-line (BEOL) process) are offset in advance. Thus, according to the processing method of some embodiments, the mask design can be monitored and adjusted in real time, and the inspection time for overlay shift between patterned material layers can be reduced, thereby greatly improving the production yield and saving the production cost.

### BRIEF DESCRIPTION OF THE DRAWINGS

FIG. 1 is a flow chart illustrating a processing method of predicting overlay shift, in accordance with some embodiments of the present disclosure.

FIG. 2A depicts an upper dummy layer that is ideally deposited on a lower dummy layer in an inspection region of a wafer.

FIG. 2B depicts an upper dummy layer that is offset from a lower dummy layer in an inspection region of a wafer.

FIG. 3A depicts a wafer having several inspection regions, in accordance with some embodiments of the present disclosure.

FIG. 3B is an enlarging view illustrating one of the inspection regions of FIG. 3A.

FIG. 4, FIG. 4-1, FIG. 4-2 and FIG. 4-3 are top views of the original alignment mark without any overlay shift and three split alignment marks with predetermined overlay shifts respectively, in accordance with some embodiments of the present disclosure.

FIG. 5A depicts an original after-etch inspection (AEI) overlay data, in accordance with some embodiments of the present disclosure.

FIG. 5B depicts an original after-develop inspection (ADI) overlay data, in accordance with some embodiments of the present disclosure.

FIG. 5C depicts an ADI pre-bias data, in accordance with some embodiments of the present disclosure.

FIG. 6 depicts an ADI pre-bias data of the original alignment marks (as shown in FIG. 4) in the inspection regions of the wafer, in accordance with some embodiments of the present disclosure.

FIG. 6-1 depicts an ADI pre-bias data of the split alignment marks split 1 (as shown in FIG. 4-1) in the inspection regions of the wafer, in accordance with some embodiments of the present disclosure.

FIG. 6-2 depicts an ADI pre-bias data of the split alignment marks split 2 (as shown in FIG. 4-2) in the inspection regions of the wafer, in accordance with some embodiments of the present disclosure.

FIG. 6-3 depicts an ADI pre-bias data of the split alignment marks split 3 (as shown in FIG. 4-3) in the inspection regions of the wafer, in accordance with some embodiments of the present disclosure.

FIG. 7 depicts an ADI pre-bias data of the original alignment marks (as shown in FIG. 4) in the inspection regions of the wafer after the second process variation occurs, in accordance with some embodiments of the present disclosure.

FIG. 7-1 depicts an ADI pre-bias data of the split alignment marks split 1 (as shown in FIG. 4-1) in the inspection regions of the wafer after the second process variation occurs, in accordance with some embodiments of the present disclosure.

FIG. 7-2 depicts an ADI pre-bias data of the split alignment marks split 2 (as shown in FIG. 4-2) in the inspection regions of the wafer after the second process variation occurs, in accordance with some embodiments of the present disclosure.

FIG. 7-3 depicts an ADI pre-bias data of the split alignment marks split 3 (as shown in FIG. 4-3) in the inspection regions of the wafer after the second process variation occurs, in accordance with some embodiments of the present disclosure.

### DETAILED DESCRIPTION

The following description provides various embodiments, or examples, for implementing different features of the present disclosure. Specific examples of components and arrangements are described below to simplify the present disclosure. These are, of course, merely examples and are not intended to be limiting. It should be understood that the embodiments may be realized in software, hardware, firmware, or any combination thereof. The terms “comprises”, “comprising”, “includes”, and/or “including” when used herein, specify the presence of stated features, integers, steps, operations, elements, and/or components, but do not preclude the presence or addition of one or more other features, integers, steps, operations, elements, components, and/or groups thereof.

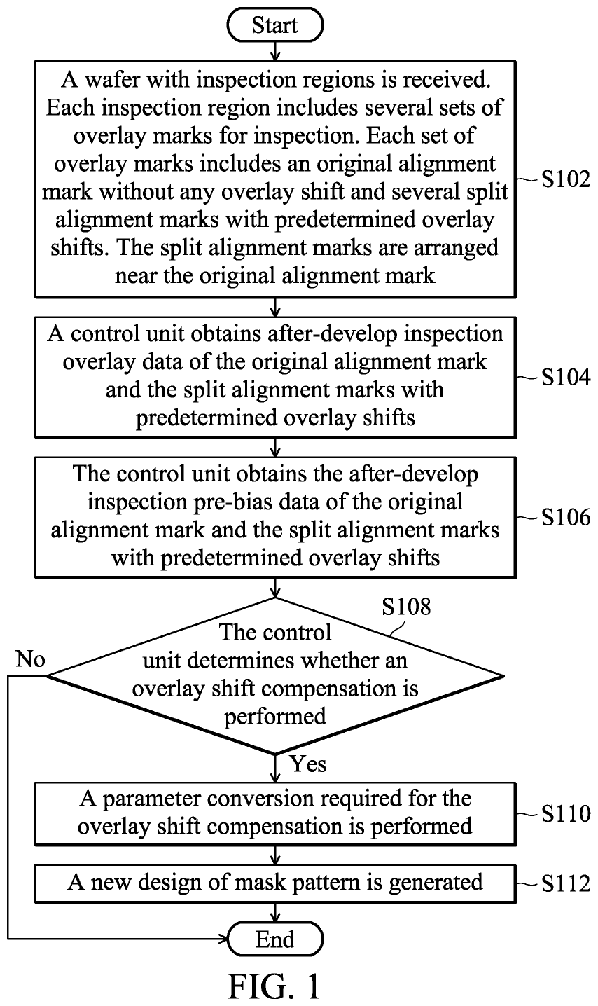

FIG. 1 is a flow chart illustrating a processing method of predicting overlay shift, in accordance with some embodiments of the present disclosure. In step S102, a wafer with inspection regions is received. The inspection regions each include several sets of overlay marks for inspection. Each of the sets of overlay marks includes an original alignment mark without any overlay shift (also can be referred to as a POR alignment mark), and several split alignment marks with predetermined overlay shifts. The split alignment marks are arranged near the original alignment mark. Some exemplary overlay marks for inspection in accordance with some embodiments will be described in more detail below (referring to the overlay marks in FIGS. 3A, 3B, 4, 4-1, 4-2 and 4-3).

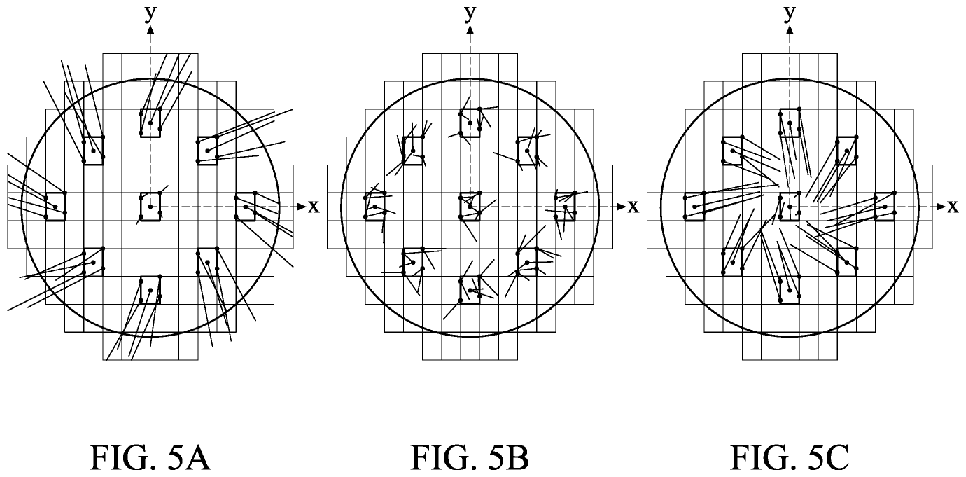

In addition, in some embodiments, the original after-etch inspection (AEI) overlay data of the wafer is stored in a storage unit. The original AEI overlay data is obtained from the regions that have been etched by an etching process. In some embodiments, the storage unit is coupled to a control unit. The aforementioned storage unit is, for example, a memory or another unit with a storage function. The aforementioned control unit is, for example, a processor or any unit with arithmetic logic function and control function. Acquisition of the original AEI overlay data in accordance with some embodiments will be described in more detail below (referring to FIGS. 5A, 5B and 5C).

It should be noted that the original AEI overlay data of the wafer that is stored in the storage unit could be reused according to the method in some embodiments of the present disclosure. Therefore, even if a process variation occurs, such as changing the processing tools and equipment (such as the deposition equipment) or varying the deposition parameters, there is no need to collect the original AEI overlay data of the wafer again.

In step S104, the control unit obtains after-develop inspection (ADI) overlay data of the original alignment mark (i.e., the POR alignment mark) and the split alignment marks with predetermined overlay shifts.

In step S106, the control unit obtains the ADI pre-bias data of the original alignment mark and the split alignment marks with predetermined overlay shifts. In some embodiments, the ADI overlay data are compared with the original AEI overlay data by the control unit, thereby acquiring the ADI pre-bias data of the original alignment mark and the split alignment marks with predetermined overlay shifts. Details of the ADI pre-bias data of the original alignment mark and the split alignment marks with predetermined overlay shifts, in accordance with some embodiments, will be described below (referring to FIGS. 6, 6-1, 6-2 and 6-3).

In step S108, the control unit determines whether an overlay shift compensation is performed according to the acquired ADI pre-bias data. If the control unit determines that there is no need to perform the overlay shift compensation, the processing method is terminated. Details for determining whether an overlay shift compensation is performed in accordance with some embodiments will be described in the following examples.

If the control unit determines that an overlay shift compensation needs to be performed, the method proceeds to step S110 to complete a parameter conversion required for the overlay shift compensation.

After the parameter conversion that is required for the overlay shift compensation is completed, in accordance with some embodiments of the present disclosure, the method proceeds to step S112, and a new design of mask pattern is generated and provided for layout design.

An exemplary embodiment that is applied to a back-end-of-line (BEOL) process is provided below for illustrating how to predict the conditions of the wires and underlying conductive vias (for example, the aluminum wires and the underlying tungsten vias (i.e., tungsten contacts)) above the wafer, thereby determining whether the process factors have undesirable effect on the overlay of the wires on the conductive vias. In addition, the following exemplary embodiments are provided for illustrating how to perform overlay shift compensation if needed.

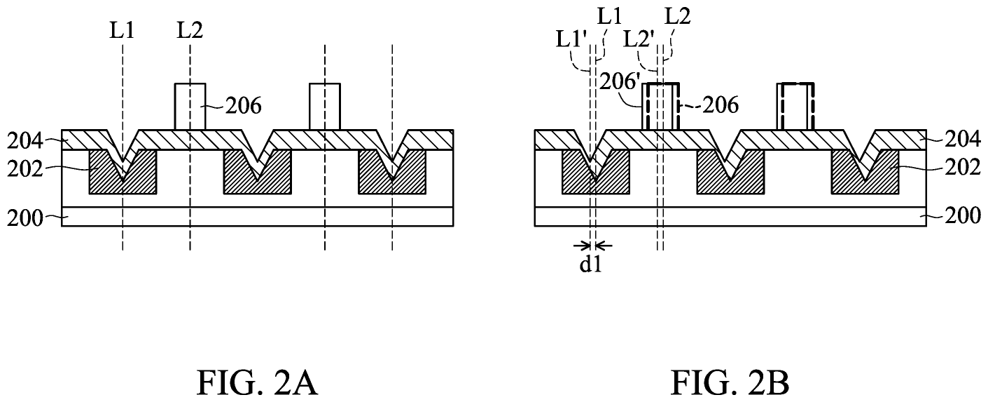

Referring to FIG. 2A, a first dummy layer 202 is formed over a substrate 200 and positioned correspondingly in an inspection region of a wafer. A second dummy layer 204 is conformally deposited on the first dummy layer 202, and a photoresist layer 206 is formed on the second dummy layer 204. The substrate 200 includes, for example, a wafer base and related material layers formed on the wafer base. In some embodiments, the first dummy layer 202 is a metal tungsten layer, and the second dummy layer 204 is a metal aluminum layer. The first dummy layer 202 and the second dummy layer 204, for example, extend into the chip region of the wafer and serve as a tungsten contact layer and an aluminum layer, respectively. The photoresist layer 206 provides a suitable photoresist pattern on the aluminum layer in the chip region, and then the aluminum layer is patterned according to the photoresist pattern to form aluminum wires. In general, whether an overlay shift between the components (such as the aluminum wires and the underlying tungsten contacts) in the chip region occurs can be predicted and determined according to the overlay marks of the first dummy layer 202 and the second dummy layer 204 in the inspection regions of the wafer.

As shown in FIG. 2A, when the centerline of the concave portion of the second dummy layer 204 coincides with the centerline L1 of the concave portion of the first dummy layer 202, it means that the second dummy layer 204 is ideally deposited on the first dummy layer 202. Therefore, the photoresist pattern of the photoresist layer 206 can accurately define the pattern of the second dummy layer 204. Accordingly, there are identical distances (i.e. ideally symmetrical arrangement) between the centerline L2 of the photoresist pattern and the portions of the first dummy layer 202 that are on both sides of the centerline L2 in the inspection region. This indicates that an ideal overlay condition between two components such as the aluminum wires and the underlying tungsten contacts exists in the chip region.

However, the second dummy layer 204 may be asymmetrically deposited on the first dummy layer 202 due to the influence of process factors, such as the material sputtering angle or other deposition parameters, the wafer warpage, the change of processing tools or equipment, or another factor.

As shown in FIG. 2B, the centerline L1′ of the concave portion of the second dummy layer 204 does not coincide with the centerline L1 of the concave portion of the first dummy layer 202. It means that the second dummy layer 204 is not ideally deposited on the first dummy layer 202. That is, the second dummy layer 204 is offset from the first dummy layer 202. Therefore, the photoresist pattern of the photoresist layer 206′ cannot accurately define the pattern of the second dummy layer 204. In FIG. 2B, there are different distances (i.e. asymmetrical arrangement) between the centerline L2′ of the photoresist pattern and the portions of the first dummy layer 202 that are on both sides of the centerline L2′ in the inspection region. This indicates that an overlay shift condition of two components exists in the chip region. For example, there is an offset distance dl between the aluminum wires and the underlying tungsten contacts in the chip region.

However, in the convention inspection method, whether it is the ideal deposition of the components as shown in FIG. 2A or the offset deposition of the components as shown in FIG. 2B, the overlay condition of the components would not be known until a patterned second dummy layer is formed by an etching process. Whether the offset deposition of the components occurs is determined by inspecting the overlay marks after etching. That is, according to the convention inspection method, an overlay condition of the components cannot be known before an etching process is performed on the second dummy layer.

Some embodiments are described below. A new design of overlay marks in the inspection region of the wafer is provided, in accordance with some embodiments of the present disclosure. By using related ADI overlay data, whether a patterned upper material layer over the substrate is offset from a patterned lower material layer can be predicted in advance before an etching process is actually performed on the upper material layer. Therefore, formation of the patterned material layers can be improved in the early stage of the manufacturing process, and the pattern accuracy of the related patterned material layers can be enhanced, in accordance with some embodiments of the present disclosure.

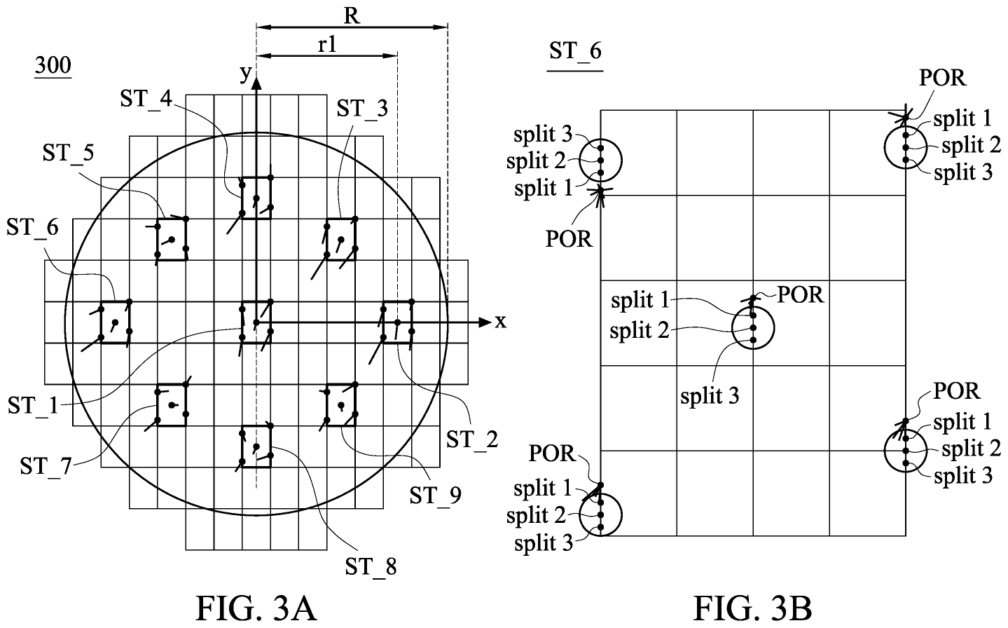

In some embodiments, several inspection regions are defined on a wafer 300. As shown in FIG. 3A, for example, nine inspection regions ST_1, ST_2, ST_3, ST_4, ST_5 ST_6, ST_7, ST_8, ST_9 are defined on the wafer 300. One of the inspection regions, such as the inspection region ST_1, corresponds to the center of the wafer 300. The other inspection regions, such as the inspection regions ST_2 to ST_9, are defined in the portions that are close to the edge of the wafer 300. In general, the edge of the wafer has a greater degree of warpage than the center of the wafer, so that the overlay marks that are closer to the edge of the wafer are more likely to be shifted.

In some embodiments, the inspection regions ST_2 to ST_9 are evenly distributed on a virtual circle within the wafer 300. The wafer 300 has a radius R. In one example, the aforementioned virtual circle is concentric with the wafer 300, and the virtual circle has a radius r1. The radius r1 is less than the radius R (r1<R). The radius r1 is in a range of, for example, greater than half of the radius R and less than the radius R (i.e., R/2<r1<R), or greater than two-third of the radius R and less than the radius R (i.e., 2R/3<r1<R). However, those ranges are provided for exemplification, and the present disclosure is not particularly limited thereto.

In some embodiments, each of the inspection regions includes several sets of overlay marks for inspection. For example, one inspection region (such as the inspection region ST_6) includes five sets of overlay marks for inspection, as shown in FIG. 3B. Each of the sets of overlay marks includes an original alignment mark POR without any overlay shift, and several split alignment marks with predetermined overlay shifts that are arranged near the original alignment mark POR. For example, three split alignment marks split 1, split 2 and split 3 are arranged near the original alignment mark POR in FIG. 3B.

In addition, in some embodiments, those sets of overlay marks in the inspection regions are arranged in the non-chip regions of the wafer. As shown in FIG. 3A and FIG. 3B, each of the inspection regions is a chip region. A chip region includes several semiconductor dies. For example, a chip region may include 20 semiconductor dies, and the chip regions are separated from each other by scribe lines. Thus, the chip region is surrounded by the scribe lines. In some embodiments, the sets of overlay marks are located in the scribe lines. In the subsequent process, these overlay marks will be trimmed and removed, and will not appear in the chip regions (or die regions).

As shown in FIG. 3B, the split alignment marks split 1, split 2 and split 3 have different predetermined overlay shifts. In other words, in this exemplified embodiment, there are five original alignment marks POR without any overlay shift, five split alignment marks split 1, five split alignment marks split 2 and five split alignment marks split 3 in the inspection region ST_6.

In this exemplified embodiment, the rest of the inspection regions in FIG. 3A each may also include five sets of overlay marks for inspection, as shown in FIG. 3B. Five points in each of the inspection regions in FIG. 3A represent the five sets of overlay marks in the each of the inspection regions for inspection. Details of the sets of overlay marks for inspection in the rest of the inspection regions can be referred to the above-mentioned descriptions of the related contents in FIG. 3B, and are not repeated herein for the sake of simplicity and clarity.

FIGS. 4, 4-1, 4-2 and 4-3 illustrate top views of the POR alignment mark and three split alignment marks with predetermined overlay shifts respectively, in accordance with some embodiments of the present disclosure. Each of the POR alignment mark and the split alignment marks includes a first dummy pattern C2 of a lower material layer and a second dummy pattern M2 of an upper material layer. In one of applications, the first dummy pattern C2 is a pattern of a patterned tungsten layer, and the second dummy pattern M2 is a pattern of a patterned aluminum layer.

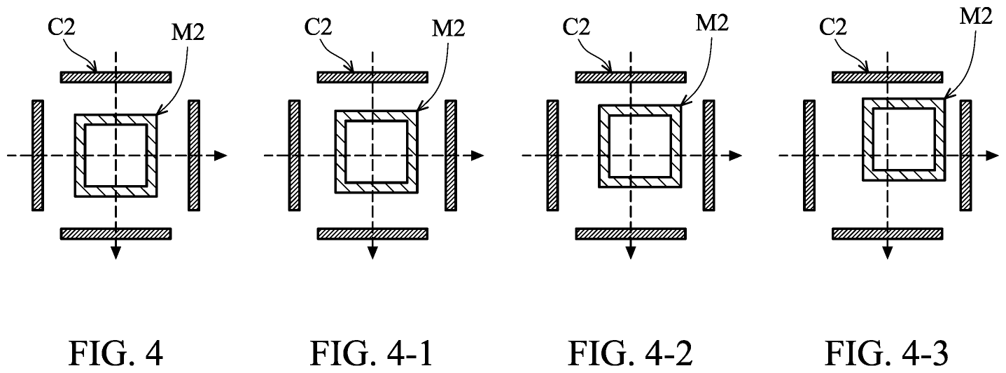

Referring to the original alignment mark POR as depicted in FIG. 4, in this exemplified embodiment, the second dummy pattern M2 is not offset from the first dummy pattern C2. That is, the symmetric center of the second dummy pattern M2 coincides with the symmetric center of the first dummy pattern C2.

Referring to the split alignment marks split 1 as depicted in FIG. 4-1, in this exemplified embodiment, the second dummy pattern M2 is offset from the first dummy pattern C2. Specifically, the symmetric center of the second dummy pattern M2 is offset from the symmetric center of the first dummy pattern C2 by a first distance. For example, the symmetric center of the second dummy pattern M2 may be shifted from the symmetric center of the first dummy pattern C2 by 10 nm in the X direction and 10 nm in the Y direction, which can also be abbreviated as X/Y=10 nm/10 nm.

Referring to the split alignment marks split 2 as depicted in FIG. 4-2, in this exemplified embodiment, the second dummy pattern M2 is offset from the first dummy pattern C2. Specifically, the symmetric center of the second dummy pattern M2 is offset from the symmetric center of the first dummy pattern C2 by a second distance. For example, the symmetric center of the second dummy pattern M2 may be shifted from the symmetric center of the first dummy pattern C2 by 30 nm in the X direction and 30 nm in the Y direction, which can also be abbreviated as X/Y=30 nm/30 nm.

Referring to the split alignment marks split 3 as depicted in FIG. 4-3, in this exemplified embodiment, the second dummy pattern M2 is offset from the first dummy pattern C2. Specifically, the symmetric center of the second dummy pattern M2 is offset from the symmetric center of the first dummy pattern C2 by a third distance. For example, the symmetric center of the second dummy pattern M2 may be shifted from the symmetric center of the first dummy pattern C2 by 60 nm in the X direction and 60 nm in the Y direction, which can also be abbreviated as X/Y=60 nm/60 nm.

In some other embodiments, more split alignment marks with predetermined overlay shifts, such as five, ten or more split alignment marks, can be arranged near the original alignment mark POR, as long as the space of the scribe line is sufficient for arranging the original alignment mark POR and those split alignment marks near the original alignment mark POR. The more the split alignment marks with predetermined overlay shifts used in the method, the better the prediction and compensation for overlay shift. In addition, the predetermined overlay shifts in finer scales, such as x/y=10 nm/10 nm, x/y=20 nm/20 nm, x/y=25 nm/25 nm, x/y=30 nm/30 nm, x/y=35 nm/35 nm, x/y=40 nm/40 nm, . . . , x/y=60 nm/60 nm, etc., can be selected for setting the split alignment marks. By using the embodied method and the predetermined overlay shifts in finer scales, the overlay shift can be predicted more accurately, thereby performing more accurate overlay shift compensation.

In some embodiments, the original AEI overlay data of the wafer is obtained and stored in the storage unit. The original after-etch inspection (AEI) overlay data can be obtained by the following steps. Before any overlay shift compensation is performed, the dummy layers are deposited over the wafer and then etched by etching processes to form an upper patterned dummy layer and a lower patterned dummy layer. Then the overlay of the upper patterned dummy layer relative to the lower patterned dummy layer is inspected to obtain the original AEI overlay data.

Referring to FIG. 5A, the original AEI overlay wafer map data is used as the original AEI overlay data for quick observation. The line segment that connects each point (represents one set of overlay marks) in the wafer map represents the magnitude of a vector. In addition, according to the original AEI overlay wafer map data, the longer line segment has a greater magnitude of the vector, which means the more severe the degree of overlay shift.

In addition, after the upper dummy layer (such as the second dummy layer 204 in FIG. 2B) is deposited and a patterned PR is formed thereon, an original ADI overlay data of the upper dummy layer in the inspection regions is obtained before the upper dummy layer is actually etched in the pattering process. As shown in FIG. 5B, an original ADI overlay wafer map data is used as the original ADI overlay data for quick observation, in accordance with some embodiments of the present disclosure.

Please refer to the wafer map data in FIG. 5A and FIG. 5B. In FIG. 5B, the vector of each of the points in the inspection regions has small magnitude (which means that no overlay shift exists). However, in FIG. 5A, the vector of each of the points in the inspection regions has large magnitude (which means that a certain degree of overlay shift exists). Accordingly, an actual overlay shift that is generated after etching cannot be known only from the ADI overlay data.

In addition, in some embodiments, an original ADI pre-bias data without any overlay shift compensation can be obtained by comparing the original AEI overlay data with the original ADI overlay data using the control unit. In this exemplified embodiment, the original AEI overlay wafer map data (FIG. 5A) is compared with the original ADI overlay wafer map data (FIG. 5B) by the control unit. The difference between the AEI overlay wafer map data (FIG. 5A) and the ADI overlay wafer map data (FIG. 5B) is referred to as an original ADI pre-bias wafer map data (FIG. 5C).

According to the descriptions above, the ADI pre-bias data, which is the difference between the ADI overlay data and the AEI overlay data, indicates the overlay shift condition. Therefore, the ADI pre-bias data that are generated from of the split alignment marks with predetermined overlay shifts (such as the split alignment marks split 1, split 2 and split 3) in the inspection regions are acquired. Then, one of the ADI pre-bias data that is generated from the respective one of the split alignment marks may be chosen for compensating the original AEI overlay data (FIG. 5A), in accordance with some embodiments of the present disclosure. According to the ADI pre-bias data of the selected split alignment marks, the predetermined overlay shift of the selected split alignment marks of the dummy pattern (for example, a predetermined overlay shift represented as X/Y predetermined offset value of 60 nm/60 nm (i.e., X/Y=60 nm/60 nm) for the second dummy pattern M2 and the first dummy pattern C2 in the split alignment marks split 3) can be conversed through a suitable parameter conversion to obtain a compensation value of overlay mark shift. The parameter conversion may be performed by the control unit. The control unit may generate a new design of mask pattern based on the compensation value of overlay mark shift.

Taking the above exemplified embodiment as an example, the following describes how to determine whether an overlay shift compensation is performed according to the acquired ADI pre-bias data.

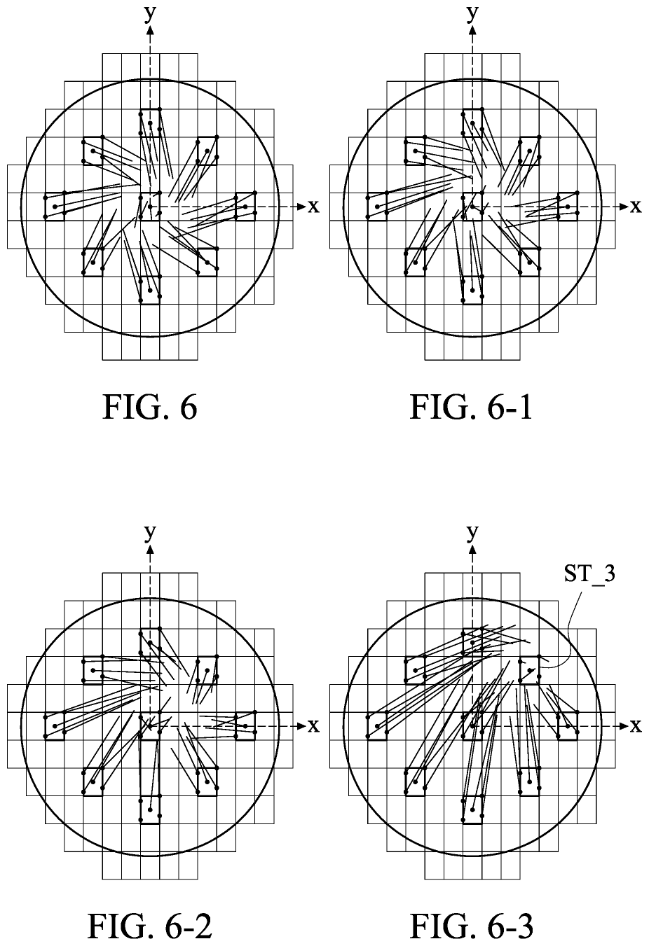

Referring to FIGS. 6, 6-1, 6-2 and 6-3, in this exemplified embodiment, the ADI pre-bias wafer map data are used as the ADI pre-bias data for quick observation. In this exemplified embodiment, the ADI overlay data of the original alignment mark POR is compared with the original AEI overlay data of the original alignment mark POR (for example, obtained from the FIG. 5A) by the control unit, so as to obtain an ADI pre-bias data for the original alignment mark POR as shown in FIG. 6. Similarly, the ADI overlay data of the split alignment marks split 1 is compared with the original AEI overlay data of the split alignment marks split 1 (for example, obtained from the FIG. 5A) by the control unit, so as to obtain an ADI pre-bias data for the split alignment marks split 1 as shown in FIG. 6-1. Similarly, the ADI overlay data of the split alignment marks split 2 is compared with the original AEI overlay data of the split alignment marks split 2 (for example, obtained from the FIG. 5A) by the control unit, so as to obtain an ADI pre-bias data for the split alignment marks split 2 as shown in FIG. 6-2. Similarly, the ADI overlay data of the split alignment marks split 3 is compared with the original AEI overlay data of the split alignment marks split 3 (for example, obtained from the FIG. 5A) by the control unit, so as to obtain an ADI pre-bias data for the split alignment marks split 3 as shown in FIG. 6-3.

Results of the ADI pre-bias wafer map data in FIGS. 6, 6-1, 6-2 and 6-3 show the vector magnitudes of the points in the inspection regions of the wafer. There are several points in each of the inspection regions (e.g., five points in each inspection region), and each point represents a set of overlay marks for inspection. Each of the sets of overlay marks includes an original alignment mark POR without any overlay shift, and several split alignment marks with predetermined overlay shifts that are arranged near the original alignment mark POR. For example, three split alignment marks split 1, split 2 and split 3 are arranged near the original alignment mark POR. In addition, the vectors of the points vary with the change of the predetermined overlay shifts represented as X/Y predetermined offset values. As shown in FIG. 6-3, in one embodiment, the vectors of the points converge to the minimum lengths in the inspection region ST_3, which indicates that the overlay shift due to process variations can be compensated by the X/Y predetermined overlay shift of 60 nm/60 nm of the split alignment marks split 3.

In addition, in some embodiments, a compensation value of overlay mark shift can be obtained by adequate parameter conversion. The control unit may generate a new design of mask pattern based on the compensation value of overlay mark shift. In some embodiments, a compensation value of overlay mark shift is obtained by dividing the X/Y predetermined offset value by the radius of the wafer. For example, in this exemplified embodiments, when the control unit determines that the overlay shift can be compensated by the inspection region ST_3 (X/Y=60 nm/60 nm) and the radius of the wafer is 150 mm, the compensation value of overlay mark shift is 0.9 ppm (=60 nm/150 mm). The compensated mask design will result in the etched patterns on the wafer (especially near the edge of the wafer) with reduced overlay shift or even no overlay shift.

In addition, during the actual deposition of the material layers, the deposition of the material layers may be affected by the process factors, such as material sputtering angle or other deposition parameters, wafer warpage, change of processing tools or equipment, or another factor, so that the deposition of the material layers changes. Thus, the compensation value of overlay mark shift that is previously determined may no longer be applicable. According to the processing method of some embodiments, when the process changes, it is not necessary to perform an actual etching process on the dummy layer that is deposited on the wafer again to obtain the original AEI overlay data of the wafer. It is only required to obtain the new ADI overlay data and compared with the original AEI overlay data that is previous stored to obtain new ADI pre-bias data after the process variation. By using the new obtained ADI pre-bias data, whether the patterned upper material layer over the wafer is offset from the patterned lower material layer can be predicted in advance before an etching process is actually performed on the upper material layer. In addition, the predetermined offset value of the split alignment marks (such as split 1, split 2 or split 3) that is determined by the control unit can be conversed through a suitable parameter conversion to obtain a new compensation value of overlay mark shift. The new compensation value of overlay mark shift is fed back to the lithography process, and a new design of mask pattern is generated to comply with the process variation. Therefore, the processing method in accordance with some embodiments of the present disclosure can save the process time and improve production efficiency.

The following is a continuation of the above example to provide an embodiment illustrating how to apply the embodied method to predict in advance whether a patterned upper material layer over the substrate is offset from a patterned lower material layer before an etching process is actually performed when the process varies.

According to the descriptions of the above example, when the first process variation occurs, it is assumed that the overlay shift due to process variations can be compensated by the X/Y predetermined overlay shift of 60 nm/60 nm of the split alignment marks split 3. As shown in FIG. 6-3, the vectors of the points converge to the minimum lengths in the inspection region ST_3. However, when the second process variation (such as change of the processing tool/equipment or deposition parameters) occurs, the X/Y predetermined overlay shift of 60 nm/60 nm of the split alignment marks split 3, which is previously determined for first overlay shift compensation, may no longer be applicable for the second process variation. Accordingly, after the second process variation occurs, a new design of mask pattern for complying with the second process variation is generated based on a new obtained ADI pre-bias data.

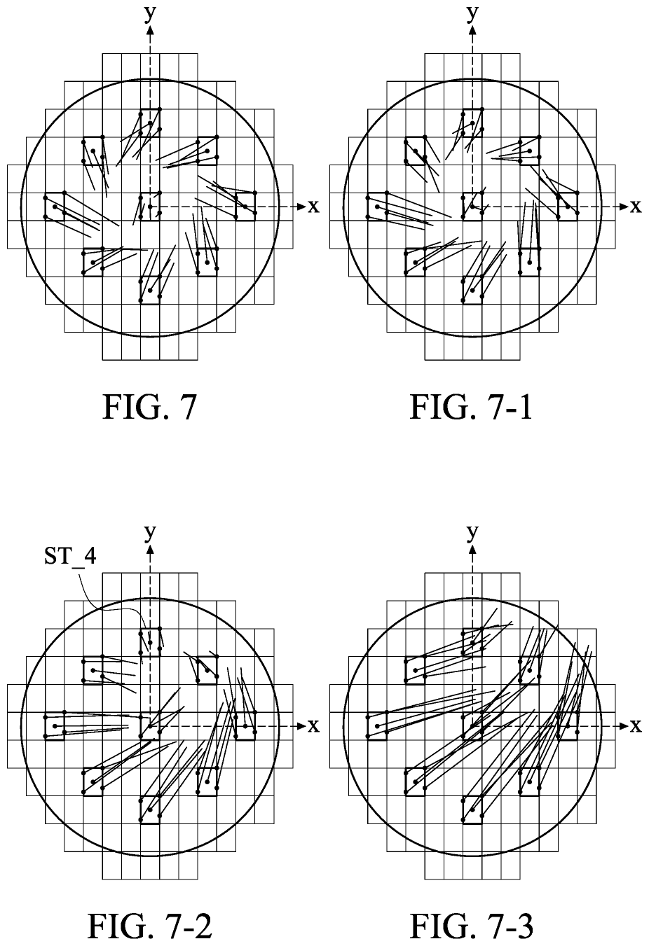

Referring to FIGS. 7, 7-1, 7-2 and 7-3, in this exemplified embodiment, the ADI pre-bias wafer map data are used as the ADI pre-bias data for quick observation. In this exemplified embodiment, when the second process variation occurs, the ADI overlay data of the original alignment mark POR is compared with the previously stored original AEI overlay data (FIG. 5A) by the control unit, so as to obtain an ADI pre-bias data for the original alignment mark POR as shown in FIG. 7. Similarly, when the second process variation occurs, the ADI overlay data of the split alignment marks split 1 (not shown) are compared with the previously stored original AEI overlay data (FIG. 5A) by the control unit, so as to obtain an ADI pre-bias data for the split alignment marks split 1 as shown in FIG. 7-1. Similarly, when the second process variation occurs, the ADI overlay data of the split alignment marks split 2 (not shown) are compared with the previously stored original AEI overlay data (FIG. 5A) by the control unit, so as to obtain an ADI pre-bias data for the split alignment marks split 2 as shown in FIG. 7-2. Similarly, when the second process variation occurs, the ADI overlay data of the split alignment marks split 3 (not shown) are compared with the previously stored original AEI overlay data (FIG. 5A) by the control unit, so as to obtain an ADI pre-bias data for the split alignment marks split 3 as shown in FIG. 7-3.

The ADI pre-bias wafer map data of FIGS. 7, 7-1, 7-2 and 7-3 that are obtained after the second process variation occurs are significantly different from the previously obtained ADI pre-bias wafer map data of FIGS. 6, 6-1, 6-2 and 6-3, respectively. This indicates that the deposition of the material layers during the second process variation is different from the deposition of the material layers during the first process variation. That is, the process variation does have effect on the deposition of the material layers.

According to the ADI pre-bias wafer map data in FIGS. 7, 7-1, 7-2 and 7-3, the vectors of the points (i.e. each point represents a set of overlay marks for inspection) vary with the change of the predetermined overlay shifts represented as X/Y predetermined offset values. As shown in FIG. 7-2, the vectors of the points converge to the minimum lengths in the inspection region ST_4. This indicates that the new overlay shift that is caused by the second process variation can be compensated by the X/Y predetermined overlay shift of 30 nm/30 nm (i.e., X/Y=30 nm/30 nm) of the split alignment marks split 2.

In addition, in some embodiments, a new compensation value of overlay mark shift can be obtained by adequate parameter conversion. The control unit re-generates a new design of mask pattern based on the new compensation value of overlay mark shift to compensate the overlay shift caused by the second process variation.

In some embodiments, a compensation value of overlay mark shift is obtained by dividing the X/Y predetermined offset value by the radius of the wafer. For example, in this exemplified embodiments, when the control unit determines that the overlay shift can be compensated by the inspection region ST_4 in FIG. 7-2 (X/Y=30 nm/30 nm) and the radius of the wafer is 150 mm, the compensation value of overlay mark shift is the quotient of 30 nm divided by 150 mm (=30 nm/150 mm). The compensated mask design will result in the etched patterns on the wafer (especially near the edge of the wafer) with reduced overlay shift or even no overlay shift.

According to the processing method of some embodiments, when the process changes again, for example, the third process variation occurs (such as changing the deposition tool/equipment, varying the deposition parameters or another factor of process), it is not necessary to perform an actual etching process on the dummy layer that is deposited on the wafer to obtain the original AEI overlay data of the wafer. It is only required to obtain the new ADI overlay data and compared with the previously stored original AEI overlay data to obtain new ADI pre-bias data after the third process variation. By using the new obtained ADI pre-bias data, whether the patterned upper material layer over the wafer is offset from the patterned lower material layer can be predicted in advance before an etching process is actually performed on the upper material layer. In addition, the predetermined offset value of the split alignment marks (such as split 1, split 2 or split 3) that is determined by the control unit can be conversed through a suitable parameter conversion to obtain another new compensation value of overlay mark shift. This new compensation value of overlay mark shift is fed back to the lithography process again. Therefore, a new design of mask pattern can be re-generated to comply with the third process variation.

According to the above examples, as shown in FIGS. 6, 6-1, 6-2 and 6-3 and FIGS. 7, 7-1, 7-2 and 7-3, the ADI pre-bias wafer map data are used as the ADI pre-bias data for quick observation of overlay shift compensation. However, the present disclosure is not limited to the use of the wafer map data. In some other embodiments, the ADI pre-bias data of the overlay marks in the inspection regions can be calculated by the control unit, thereby determining which split alignment mark with a X/Y predetermined offset value is relevant for overlay shift compensation. One of the calculation methods is described below for illustration.

For example, the ADI pre-bias data of the five sets of overlay marks in each of the inspection regions, such as five original alignment mark POR, five several split alignment marks Split 1, five several split alignment marks Split 2 and five several split alignment marks Split 3 with predetermined overlay shifts in each of the inspection regions, can be calculated numerically. According to the numerical calculation results among several split alignment mark with different predetermined overlay shift, it can be determined which split alignment mark makes the vectors of the points in the inspection region converge to the smallest value or the closest value to zero after calculation.

The data in FIGS. 6, 6-1, 6-2 and 6-3 are used as an example for numerical calculation. Among all of the calculation results of the ADI pre-bias data in the inspection regions, the sum (which is abbreviated as “M3S value”) of the average value and three times of the standard deviation of the inspection region ST_3 in FIG. 6-3 is the smallest according to the calculation results. The result of the smallest “M3S value” means that the vectors of the points converge to the minimum lengths in the inspection region ST_3 of FIG. 6-3. Accordingly, the overlay shift due to process variations can be compensated by the X/Y predetermined overlay shift of 60 nm/60 nm of the split alignment marks split 3.

Table 1 lists the calculation results of the average values, the standard deviations and the “M3S value” in the X direction and the Y direction from the ADI pre-bias data of the inspection region ST_3 in FIG. 6-3. Among all of the calculation results of the ADI pre-bias data in the inspection regions, the “M3S value” calculated from the data of five sets of overlay marks in the inspection region ST_3 of FIG. 6-3 is the smallest (i.e. the closest value to zero). Accordingly, the calculation result indicates that the predetermined overlay shift (i.e., X/Y=60 nm/60 nm) of the split alignment marks split 3 is a relevant value for overlay shift compensation.

TABLE 1

| | X | Y |
|---|---|---|
| N (i.e., the number of sets of overlay marks in one | 5 | 5 |
| inspection region) | | |
| average value | −1.5 | −3.1 |
| standard deviation | 1.2 | 1.6 |
| average value + 3 × standard deviation (M3S) | 5 | 7.9 |

In addition, the data in FIGS. 7, 7-1, 7-2 and 7-3 are used as another example for numerical calculation. Among all of the calculation results of the ADI pre-bias data in the inspection regions, the “M3S value” of the average value and three times of the standard deviation of the inspection region ST_4 in FIG. 7-2 is the smallest according to the calculation results. The result of the smallest “M3S value” means that the vectors of the points converge to the minimum lengths in the inspection region ST_4 of FIG. 7-2. Accordingly, the overlay shift due to second process variation can be compensated by the X/Y predetermined overlay shift of 30 nm/30 nm of the split alignment marks split 2.

Table 2 lists the calculation results of the average values, the standard deviations and the “M3S value” in the X direction and the Y direction from the ADI pre-bias data of the inspection region ST_4 in FIG. 7-2. Among all of the calculation results of the ADI pre-bias data in the inspection regions, the “M3S value” calculated from the data of five sets of overlay marks in the inspection region ST_4 of FIG. 7-2 is the smallest (i.e. the closest value to zero). Accordingly, the calculation result indicates that the predetermined overlay shift (i.e., X/Y=30 nm/30 nm) of the split alignment marks split 2 is a relevant value for overlay shift compensation.

TABLE 2

| | X | Y |
|---|---|---|
| N (i.e., the number of sets of overlay marks in one | 5 | 5 |
| inspection region) | | |
| average value | −0.7 | −3.2 |
| standard deviation | 0.8 | 1 |
| average value + 3 × standard deviation (M3S) | 3.2 | 6 |

In some embodiments, the control unit independently produces the ADI pre-bias wafer map data as shown in FIGS. 6, 6-1, 6-2 and 6-3 and FIGS. 7, 7-1, 7-2 and 7-3, or perform the calculation method to obtain the M3S value as described in the exemplified example above, thereby determining which split alignment mark with a X/Y predetermined offset value is relevant for overlay shift compensation. In some embodiments, the control unit may produce ADI pre-bias wafer map data and perform the calculation at the same time for determining the X/Y predetermined offset value for overlay shift compensation.

According to the aforementioned descriptions, the processing methods provided in some embodiments of the present disclosure can be performed to predict overlay shift in advance by using a new design of overlay marks in the inspection regions of the wafer. An ADI pre-bias data can be obtained by comparing the ADI overlay data with the stored original AEI overlay data. According to the ADI pre-bias data, whether a patterned upper material layer over the wafer is offset from a patterned lower material layer can be predicted in advance before an etching process is actually performed. In addition, according to the processing method of the embodiments, the obtained compensation value of overlay mark shift is fed back to the lithography process to improve the manufacturing process, thereby enhancing the accuracy of pattern formation. According to the embodiments, the processing method with the prediction and early warning function does shorten the time for testing and evaluating the overlay marks. In addition, according to the processing method of some embodiments, when the process changes, it is not necessary to perform an actual etching process on the dummy layer that is deposited on the wafer again to obtain the original AEI overlay data of the wafer. It is only required to obtain new ADI pre-bias data after the process variation. By using the new obtained ADI pre-bias data, whether the patterned upper material layer over the wafer is offset from the patterned lower material layer can be predicted in advance before an etching process is actually performed on the upper material layer. In addition, the predetermined offset value of the split alignment marks, which is determined by the control unit, can be conversed through a suitable parameter conversion to obtain a new compensation value of overlay mark shift in a short time. The new compensation value of overlay mark shift can be fed back to the lithography process, and a new design of mask pattern is then generated to comply with the process variation. Therefore, according to the processing method of some embodiments of the present disclosure, the mask design can be monitored and adjusted in real time, and the inspection time for overlay shift between patterned material layers can be reduced, thereby greatly improving the production yield and saving the production cost. Therefore, the present disclosure provides a green technology for manufacturing semiconductor wafers.

The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor wafer, comprising:
a plurality of inspection regions, wherein each of the inspection regions includes sets of overlay marks for inspection, and each of the sets of overlay marks includes an original alignment mark without any overlay shift and split alignment marks with predetermined overlay shifts, wherein the split alignment marks are arranged near the original alignment mark,
wherein the sets of overlay marks in the inspection regions are arranged in non-chip regions of the semiconductor wafer, and one of the inspection regions corresponds to a center of the semiconductor wafer, while the remaining inspection regions correspond to regions that are near edges of the semiconductor wafer.

2. The semiconductor wafer as claimed in claim 1, wherein the split alignment marks with predetermined overlay shifts have different offset values in an X direction and in a Y direction, which are referred to as X/Y predetermined offset values.

3. A processing apparatus for overlay shift, applied to a semiconductor wafer with inspection regions, wherein each of the inspection regions includes sets of overlay marks for inspection, and each of the sets of overlay marks includes an original alignment mark without any overlay shift and split alignment marks with predetermined overlay shifts, and the split alignment marks are arranged near the original alignment mark, wherein the processing apparatus for overlay shift comprises:
a storage unit, storing original after-etch inspection (AEI) overlay data of the inspection regions; and
a control unit, coupled to the storage unit, wherein the control unit is configured to:
compare after-develop inspection (ADI) overlay data of the original alignment mark and the split alignment marks with the original AEI overlay data, thereby acquiring ADI pre-bias data of the original alignment mark and the split alignment marks; and
determine whether an overlay shift compensation is performed according to the acquired ADI pre-bias data.

4. The processing apparatus for overlay shift as claimed in claim 3, wherein when one of the ADI pre-bias data of the split alignment marks indicates that alignment marks in one of the inspection regions can be applied for overlay shift compensation, which is determined by the control unit, the overlay shift compensation is performed.

5. The processing apparatus for overlay shift as claimed in claim 4, wherein the split alignment marks with predetermined overlay shifts have different X/Y predetermined offset values, and when the overlay shift compensation is performed, a parameter conversion is performed by the control unit according to one of the X/Y predetermined offset values related to the ADI pre-bias data of the split alignment marks, and a result of the parameter conversion is fed back to a lithography process for the overlay shift compensation.

6. The processing apparatus for overlay shift as claimed in claim 5, wherein a compensation value of overlay mark shift is obtained by dividing the X/Y predetermined offset value by a radius of the semiconductor wafer, and wherein the overlay shift compensation is performed by the control unit in accordance with the compensation value of overlay mark shift.

7. The processing apparatus for overlay shift as claimed in claim 3, wherein when the ADI pre-bias data of the original alignment mark is proximate to the original AEI overlay data and has no overlay shift, which is determined by the control unit according to the ADI pre-bias data of the original alignment mark, the overlay shift compensation is not performed.

8. The processing apparatus for overlay shift as claimed in claim 3, wherein the original AEI overlay data is original AEI overlay wafer map data, the ADI pre-bias data of the original alignment mark and the split alignment marks are ADI pre-bias wafer map data, and the ADI pre-bias data are ADI pre-bias wafer map data.

9. The processing apparatus for overlay shift as claimed in claim 3, wherein the original AEI overlay data is generated by:
providing a reference wafer, wherein inspection regions of the reference wafer include a first dummy layer and a second dummy layer deposited on the first dummy layer;
performing a patterning process on the second dummy layer to expose portions of the first dummy layer and form a patterned second dummy layer; and
inspecting an overlay shift between the patterned second dummy layer and the first dummy layer to generate the original AEI overlay data.

10. The processing apparatus for overlay shift as claimed in claim 9, wherein the control unit is further configured to:
acquire an original ADI overlay data of the first dummy layer in the inspection regions before the patterning process is performed on the second dummy layer; and
compare the original after-etch inspection (AEI) overlay data with the original ADI overlay data to obtain an original ADI pre-bias data without compensation.

11. The processing apparatus for overlay shift as claimed in claim 9, wherein the first dummy layer serves as a tungsten contact layer, and the second dummy layer serves as an aluminum layer.

12. A processing method for overlay shift, comprising:
receiving a wafer with inspection regions, wherein each of the inspection regions includes sets of overlay marks for inspection, and each of the sets of overlay marks includes an original alignment mark without any overlay shift and split alignment marks with predetermined overlay shifts, wherein the split alignment marks are arranged near the original alignment mark;
comparing after-develop inspection (ADI) overlay data of the original alignment mark and the split alignment marks with original after-etch inspection (AEI) overlay data, thereby acquiring ADI pre-bias data of the original alignment mark and the split alignment marks; and
determining whether an overlay shift compensation is performed according to the acquired ADI pre-bias data.

13. The processing method for overlay shift as claimed in claim 12, wherein determining whether the overlay shift compensation is performed comprises:
when one of the ADI pre-bias data of the split alignment marks indicates that alignment marks in one of the inspection regions can be applied for overlay shift compensation, the overlay shift compensation is performed.

14. The processing method for overlay shift as claimed in claim 13, wherein the split alignment marks have different X/Y predetermined offset values, and when the overlay shift compensation is performed, a parameter conversion is performed according to the X/Y predetermined offset values related to the ADI pre-bias data of the split alignment marks, and the result of the parameter conversion is fed back to the lithography process for the overlay shift compensation.

15. The processing method for overlay shift as claimed in claim 14, wherein a compensation value of overlay mark shift is obtained by dividing the X/Y predetermined offset values by a radius of the wafer, and the overlay shift compensation is performed in accordance with the compensation value of overlay mark shift.

16. The processing method for overlay shift as claimed in claim 12, further comprising a step of acquiring the original AEI overlay data, wherein the step comprises:
providing a reference wafer, wherein inspection regions of the reference wafer include a first dummy layer and a second dummy layer deposited on the first dummy layer;
performing a patterning process on the second dummy layer to expose portions of the first dummy layer and form a patterned second dummy layer; and
inspecting an overlay shift between the patterned second dummy layer and the first dummy layer to obtain the original AEI overlay data.

17. The processing method for overlay shift as claimed in claim 16, further comprising:
acquiring an original ADI overlay data of the first dummy layer in the inspection regions before the patterning process is performed on the second dummy layer; and
comparing the original AEI overlay data with the original ADI overlay data to obtain an original ADI pre-bias data without compensation.

18. The processing method for overlay shift as claimed in claim 12, further comprising:
receiving a signal of process variation;
receiving another wafer having the inspection regions;
re-comparing ADI overlay data of the original alignment mark and the split alignment marks with the original AEI overlay data in storage, thereby acquiring a second set of ADI pre-bias data; and
re-determining whether the overlay shift compensation is performed according to the acquired second set of ADI pre-bias data.
